(19) United States
(12) Patent Application Publication
(10) Pub. No.: US 2023/0348778 A1
(43) Pub. Date: Nov. 2, 2023

(54) PHOTOLUMINESCENT MATERIALS WITH PHOSPHOROUS ADDITIVES TO REDUCE PHOTODEGRADATION

(71) Applicant: Applied Materials, Inc., Santa Clara, CA (US)

(72) Inventors: Kulandaivelu Sivanandan, Fremont, CA (US); Sivapackia Ganapathiappan, Los Altos, CA (US); Nag Patibandla, Dublin, CA (US)

(73) Assignee: Applied Materials, Inc., Santa Clara, CA (US)

(21) Appl. No.: 18/141,655

(22) Filed: May 1, 2023

Related U.S. Application Data
(60) Provisional application No. 63/337,243, filed on May 2, 2022.

(51) Int. Cl. C09K 11/02; H10K 59/38; H10K 71/10; B82Y 20/00; C09K 11/06

(52) U.S. Cl. CPC C09K 11/02; H10K 59/38; H10K 71/10; B82Y 20/00; C09K 11/06

(57) ABSTRACT

Multilayered semiconductor particles, which may be referred to as a quantum dots, may include a zinc-containing core. The particles may include a zinc-and-selenium-containing inner shell on the zinc-containing core. The particles may include a zinc-containing outer shell on the zinc-and-selenium-containing inner shell. The particles may include a phosphorous-containing material in contact with the zinc-containing outer shell. The phosphorous-containing material may be or include triisopropyl phosphite (TIPP), bis(2,4-di-tert-butylphenyl) pentaerythritol diphosphate (B PEDP), tris(2, 4-di-tert-butylphenyl)phosphite (TDTBPP), triethylphosphite, tris(2-ethylhexylphosphite), tris(trimethylsilyl)phosphite, triphenylphosphite, triphenyl phosphine, tris(4-methoxyphenyl)phosphine, tris(1-pyrrolidinyl)phosphine, tri(2-furyl)phosphine, or tris(dimethylamino)phosphine.

### CROSS-REFERENCE TO RELATED APPLICATIONS

This application claims the benefit of, and priority to U.S. Provisional Application Ser. No. 63/337,243, filed May 2, 2022, which is hereby incorporated by reference in its entirety for all purposes.

### TECHNICAL FIELD

The present technology relates to photoluminescent materials with photodegradation resistivity and to methods of making the same. More specifically, the present technology relates to quantum dots made of multiple layers of inorganic materials including an antioxidant.

### BACKGROUND

High-resolution light-emitting diode (LED) displays can include millions of micron-sized pixels arranged to form a viewing screen. Conventional LED displays generate a color image by filtering down white light from an LED light source into red, green, and blue pixels that emit at varying intensities across the viewing screen. Other LED displays excite organic or inorganic compounds so they emit light of a particular color, such as red, green, or blue light, depending on the pixel. These LED displays typically require fewer filters to block the light of unwanted colors, which can improve their brightness and power efficiency. Liquid crystal displays (LCDs) may include quantum dot enhancement film that offer extended color saturation. However, there are many challenges with making photoluminescent materials, including challenges with making materials that are stable over the lifetime of the display.

Thus, there is a need for high-quality materials for display devices. These and other needs are addressed by the present technology.

### SUMMARY

Embodiments of the present technology include multilayered semiconductor particles, which may be referred to as a quantum dot. The structures may include a zinc-containing core. The structures may include a zinc-and-selenium-containing inner shell on the zinc-containing core. The structures may include a zinc-containing outer shell on the zinc-and-selenium-containing inner shell. The structures may include a phosphorous-containing material in contact with the zinc-containing outer shell. The phosphorous-containing material may be or include triisopropyl phosphite (TIPP), bis(2,4-di-tert-butylphenyl) pentaerythritol diphosphate (B PEDP), tris(2, 4-di-tert-butylphenyl)phosphite (TDTBPP), triethylphosphite, tris(2-ethylhexylphosphite), tris(trimethylsilyl)phosphite, triphenylphosphite, triphenyl phosphine, tris(4-methoxyphenyl)phosphine, tris(1-pyrrolidinyl)phosphine, tri(2-furyl)phosphine, or tris(dimethylamino)phosphine.

In embodiments, the zinc-containing core may further include sulfur, selenium, or tellurium. The zinc-and-selenium-containing inner shell may further include tellurium or sulfur. The zinc-containing outer shell may further include sulfur. Each of the multilayered semiconductor particle may be characterized by a longest dimension of less than or about 4 nm. The phosphorous-containing material may be characterized by a boiling point of greater than or about 100° C. The phosphorous-containing material may be or include bis(2,4-di-tert-butylphenyl) pentaerythritol diphosphate (B PEDP), or tris(2, 4-di-tert-butylphenyl)phosphite (TDTBPP).

Some embodiments of the present technology encompass pixel structures. The pixel structures may include a light emitting diode structure operable to generate light characterized by a peak emission wavelength of greater than or about 350 nm. The pixel structures may include a photoluminescent region containing a photoluminescent material positioned on the light emitting diode structure. The photoluminescent region may include a plurality of multilayered semiconductor particles comprising an antioxidant.

In embodiments, the antioxidant includes phosphorous and may be characterized by a boiling point of greater than or about 100° C. The antioxidant may include a phosphorous-containing material. The phosphorous-containing material may be or include triisopropyl phosphite (TIPP), bis(2,4-di-tert-butylphenyl) pentaerythritol diphosphate (B PEDP), tris(2, 4-di-tert-butylphenyl)phosphite (TDTBPP), triethylphosphite, tris(2-ethylhexylphosphite), tris(trimethylsilyl)phosphite, triphenylphosphite, triphenyl phosphine, tris(4-methoxyphenyl)phosphine, tris(1-pyrrolidinyl)phosphine, tri(2-furyl)phosphine, or tris(dimethylamino)phosphine. The plurality of multilayered semiconductor particles may include a zinc-containing core, a zinc-and-selenium-containing inner shell on the zinc-containing core, and a zinc-containing outer shell on the zinc-and-selenium-containing inner shell. The photoluminescent material may include a quantum dot material. The quantum dot material may include a blue quantum dot material. Each of the multilayered semiconductor particles may be characterized by a longest dimension of less than or about 4 nm.

Some embodiments of the present technology encompass methods of fabricating a display. The methods may include forming a light emitting diode structure on a substrate. The methods may include forming a photoluminescent region on the light emitting diode structure. The methods may include forming a photoluminescent material in the photoluminescent region. The photoluminescent material may include a plurality of multilayered semiconductor particles including an antioxidant.

In embodiments, the photoluminescent material may include a blue quantum dot material. The antioxidant may include a phosphorous-containing material. The phosphorous-containing material may be or include triisopropyl phosphite (TIPP), bis(2,4-di-tert-butylphenyl) pentaerythritol diphosphate (B PEDP), tris(2, 4-di-tert-butylphenyl)phosphite (TDTBPP), triethylphosphite, tris(2-ethylhexylphosphite), tris(trimethylsilyl)phosphite, triphenylphosphite, triphenyl phosphine, tris(4-methoxyphenyl)phosphine, tris(1-pyrrolidinyl)phosphine, tri(2-furyl)phosphine, or tris(dimethylamino)phosphine. The photoluminescent material may be characterized by a longest dimension of less than or about 4 nm. The methods may include handling the photoluminescent material in a presence of oxygen or ambient white light during subsequent fabrication operations. The plurality of multilayered semiconductor particles may include a zinc-containing core, a zinc-and-selenium-containing inner shell on the zinc-containing core, and a zinc-containing outer shell on the zinc-and-selenium-containing inner shell.

Embodiments of the present technology provide improved quantum dot particles that include a phosphorous-containing material. The phosphorous-containing material may improve storage and handling of quantum dot material, such as the ink used to form quantum dot particles, as well as formed quantum dot particles. The phosphorous-containing material may serve as a sacrificial molecule and may prevent oxygen from reacting with the quantum dot. Furthermore, the phosphorous-containing additives may not inhibit the function of the quantum dot particles. These and other embodiments, along with many of their advantages and features, are described in more detail in conjunction with the below description and attached figures.

### BRIEF DESCRIPTION OF THE DRAWINGS

A further understanding of the nature and advantages of the disclosed embodiments may be realized by reference to the remaining portions of the specification and the drawings.

FIG. 1 shows a flowchart with selected operations in a method of making a multilayered semiconductor particle according to embodiments of the present technology.

FIG. 2 shows a simplified cross-sectional drawing of a multilayered semiconductor particle according to embodiments of the present technology.

FIG. 3 shows a simplified cross-sectional schematic drawing of a display device incorporating the multilayered semiconductor particles according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the figures, similar components and/or features may have the same numerical reference label. Furthermore, various components of the same type may be distinguished by following the reference label by a letter that distinguishes among the similar components and/or features. If only the first numerical reference label is used in the specification, the description is applicable to any one of the similar components and/or features having the same first numerical reference label irrespective of the letter suffix.

### DETAILED DESCRIPTION

Quantum dot particles are nanometer-sized particles of inorganic materials that can emit light of a particular color after being excited by more energetic light. The color of the emitted light may depend on one or more characteristics of the particles, including their size, shape, and composition, among other characteristics. For quantum dot particles made of inorganic semiconductor materials, the color of the light they emit depends on an energy gap between the conduction band and the valence band of the dots. When the quantum dot particles are excited, one or more electrons jump from the lower-energy valence band to the higher-energy conduction band. As the excited electrons fall back down to the valence band, they emit light having a color that depends on the size of the energy gap between the valence band and the conduction band. The narrower the energy gap, the more the emitted light is shifted to the red, while the wider the energy gap, the more the emitted light is shifted to the blue. By adjusting one or more characteristics of the quantum dot particles, such as a longest dimension of the quantum dot particles, that change the energy gap between the conduction and valence bands, quantum dot particles can be made that emit light of practically any color in the visible spectrum.

The efficiency of quantum dot particles in converting high-energy white or ultraviolet light into specific colors of visible light has made them increasingly popular to use in electronic displays such as light-emitting-diode (LED) displays and liquid crystal displays (LCDs). The ability of the quantum dot particles to emit one color of light reduces the number of color filters and polarizers needed in a display to block unwanted colors of light from contaminating the displayed images. In many cases, the quantum-dot-containing displays are brighter, higher-contrast, and more energy-efficient than conventional LED displays that lack quantum dot particles.

The inorganic semiconductor materials used to make many types of quantum dot particles may also be more stable than other kinds of color-specific photoluminescent compounds, such as many of the organic compounds used in organic-light-emitting-diode (OLED) displays. The inorganic quantum dot particles can undergo many excitation-emission cycles before chemical changes in the semiconductor materials significantly reduce their conversion efficiency. In contrast, the complex organic molecules used in OLED displays are more prone to chemical breakdown over time. The organic molecules are also more sensitive than inorganic quantum dot particles to water and other contaminants quenching their photoluminescence.

Unfortunately, there are still many challenges with efficiently fabricating quantum dot particles that are characterized by a sharp color profile centered on a precise emission wavelength. In many cases, the quantum dot particles may be sensitive to oxygen. Exposure to white light or atmosphere may allow oxygen to interact with the quantum dot particles, resulting in photodegradation of the particles. This photodegradation can reduce the lifetime of the quantum dot particles, namely blue quantum dot particles which are more sensitive to oxygen compared to red quantum dot particles and green quantum dot particles. Blue quantum dot particles may be more sensitive to photodegradation due to the high surface area and large band gap of the particle. Quantum dot materials suffering from photodegradation may realize drastic reductions in photoluminescence quantum yield (PLQY). PLQY may define the number of photons emitted per number of photons absorbed, which may measure photoluminescence of the quantum dot particles.

The present technology addresses the challenges with oxidation of quantum dot materials by incorporating materials in the formation of the quantum dot materials that reduce the susceptibility of oxidation. Embodiments of the present technology may incorporate an antioxidant in the quantum dot materials. The antioxidant may be a phosphorous-containing material that may reduce the effects of photodegradation during both formation and during use of the quantum dot materials. It has been discovered that the incorporation of the antioxidant, such as a phosphorous-containing additive, may inhibit the oxidation of the quantum dot materials as the antioxidant serves as a sacrificial material. The antioxidant may oxidize before the quantum dot materials, thus reducing the oxidation of the quantum dot materials.

The present technology is able to produce inorganic quantum dot particles that are characterized by an increased PLQY. In embodiments, the quantum dot particles may include a multilayered structure of semiconductor materials that include a particle core made from a first group of semiconductor materials, an inner shell made from a second group of semiconductor materials, an outer shell made from a third group of materials, and an antioxidant material. The antioxidant material may reduce the degradation of the quantum dot particles and may allow for less stringent processing conditions.

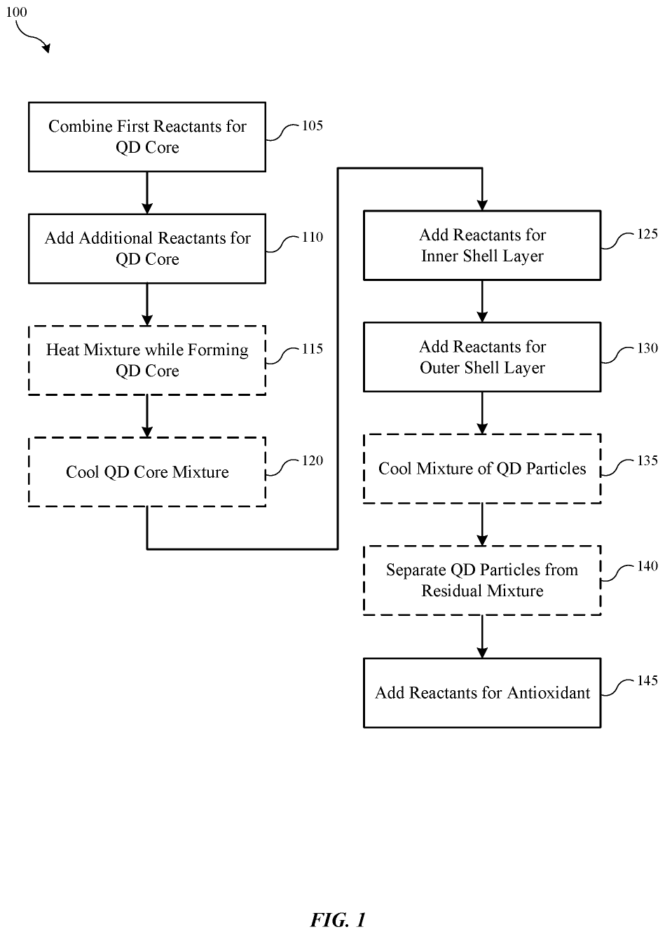

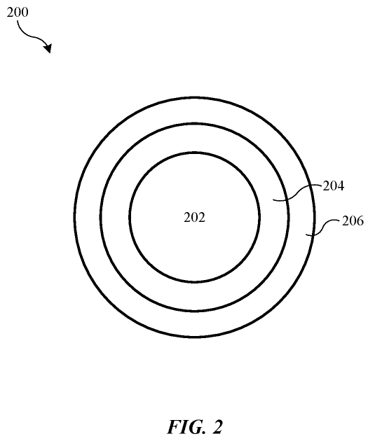

FIG. 1 shows a flowchart illustrating some of the operations in embodiments of the present methods to make a multilayered semiconductor particle. FIG. 2 shows a simplified cross-sectional drawing of an embodiment of one of those multilayered semiconductor particles made by the present technology. Method 100 shown in FIG. 1 may or may not include operations prior to the initiation of the methods, including the preparation of the reactants that are combined to make the core and shells of the multilayered semiconductor particles. Method 100 may also include a number of optional operations, which may or may not be specifically associated with some embodiments of methods according to the present technology.

Referring specifically to FIG. 1, method 100 may include combining first reactants incorporated into a core of the multilayered semiconductor particle (i.e., the quantum dot) at operation 105. In embodiments, these first reactants may be rapidly combined in a short period of time. The first reactants may be rapidly combined in less than or about 10 seconds, less than or about 7.5 seconds, less than or about 5 seconds, less than or about 2.5 seconds, less than or about 1 second, or less. The rapid combination of the reactants may reduce localized concentration centers of one of the reactants that can lead to a less uniform formation of the quantum dot cores, such as quantum dot core 202 of the multilayered semiconductor particle 200 shown in FIG. 2.

The first reactants that are combined in operation 105 may include two or more semiconductor-containing reactants. In embodiments, the first reactants may include at least one zinc-containing compound and, for example, at least one selenium-containing compound, at least one sulfur-containing compound, or at least one tellurium-containing compound, among other first reactants. The at least one zinc-containing compound may be an organo-zinc compound, among other zinc-containing compounds. The organo-zinc compound may be zinc acetate or zinc stearate, among other organo-zinc compounds. In embodiments, the organo-zinc compound may be anhydrous, such as anhydrous zinc acetate. The at least one selenium compound may be selenium complexed with an organo-phosphorous complexing agent. The organo-phosphorous complexing agent may be a trialkyl-phosphine compound. The trialkyl-phosphine compound may be one or more of trihexylphosphine, triseptylphosphine, trioctylphosphine, and trinonylphosphine, among other trialkyl phosphine compounds.

In embodiments, the first reactants may include additional compounds that facilitate the rapid combination of the at least one zinc-containing compound and the at least one selenium-containing compound. These additional compounds may include unsaturated or saturated alkyl hydrocarbons having greater than or about 10 carbon atoms, greater than or about 12 carbon atoms, greater than or about 15 carbon atoms, greater than or about 18 carbon atoms, greater than or about 20 carbon atoms or more. The alkyl hydrocarbons may include one or more of 1-octadecene, 1-decene, 1-hexadecene, 1-dodecene, 1-eicosene, and tetradecene, among other alkyl hydrocarbons. These additional compounds may include organic acids having greater than or about 12 carbon atoms, greater than or about 15 carbon atoms, greater than or about 18 carbon atoms, greater than or about 20 carbon atoms or more. For example, the organic acids may be or include one or more of acetic acid, propionic acid, butyric acid, valeric acid, caproic acid, heptanoic acid, caprylic acid, capric acid, undecanoic acid, lauric acid, myristic acid, palmitic acid, stearic acid, behenic acid, acrylic acid, methacrylic acid, but-2-enoic acid, but-3-enoic acid, pent-2-enoic acid, pent-4-enoic acid, hex-2-enoic acid, hex-3-enoic acid, hex-4-enoic acid, hex-5-enoic acid, hept-6-enoic acid, oct-2-enoic acid, dec-2-enoic acid, undec-10-enoic acid, dodec-5-enoic acid, oleic acid, gadoleic acid, erucic acid, linoleic acid, α-linolenic acid, calendic acid, eicosadienoic acid, eicosatrienoic acid, arachidonic acid, stearidonic acid, benzoic acid, para-toluic acid, ortho-toluic acid, meta-toluic acid, hydrocinnamic acid, and oleic acid, among other organic acids.

The first reactants may be combined at a temperature of greater than or about 90° C., greater than or about 100° C., greater than or about 110° C., greater than or about 120° C., greater than or about 130° C., greater than or about 140° C., greater than or about 150° C., or more. The temperature of the combined first reactants may be increased to greater than or about 160° C., greater than or about 170° C., greater than or about 180° C., greater than or about 190° C., greater than or about 200° C., greater than or about 210° C., greater than or about 220° C., or more while the combined first reactants react to form a first portion of the quantum cores. The first portion of the quantum dot cores may include zinc and selenium, sulfur, tellurium, or combinations of these.

Method 100 may include adding additional reactants to the first portion of the quantum dot cores at operation 110. These additional reactants may be rapidly added to the mixture that includes the first portion of the quantum dot cores in a short period of time. The addition time may be less than or about 10 seconds, less than or about 7.5 seconds, less than or about 5 seconds, less than or about 2.5 seconds, less than or about 1 second, or less. The rapid addition of the additional reactants may reduce localized concentration centers of one of the reactants that can lead to less uniform incorporation of the additional reactants into the first portion of the quantum dot cores. The additional reactants may include one or more tellurium-containing reactants. The tellurium-containing reactants may include tellurium complexed with an organo-phosphorous complexing agent. The organo-phosphorous complexing agent may be a trialkyl-phosphine compound. The trialkyl-phosphine compound may be one or more of trihexylphosphine, triseptylphosphine, trioctylphosphine, and trinonylphosphine, among other trialkyl phosphine compounds. The addition of the additional reactants to the first portion of the quantum dot cores may create a mixture of the quantum dot core reactants.

Method 100 may also include heating the mixture of the quantum dot core reactants at optional operation 115. In embodiments, the mixture may be heated to a temperature greater than or about 250° C., greater than or about 260° C., greater than or about 270° C., greater than or about 280° C., greater than or about 290° C., greater than or about 300° C., or more. The increase in temperature may be characterized by a temperature ramp-up rate of greater than or about 10° C./minute, greater than or about 11° C./minute, greater than or about 12° C./minute, greater than or about 13° C./minute, greater than or about 14° C./minute, greater than or about 15° C./minute, or more. The elevated temperature of the mixture may provide efficient incorporation of the additional reactants into the first portion of the quantum dot cores to form a full quantum dot core, such as quantum dot core 202. In embodiments, the quantum dot core 202 may include zinc, selenium, and tellurium in a ZnSeTe core. However, it is contemplated that the quantum dot core 202 may include sulfur in addition to zinc, selenium, and/or tellurium. The mixture of the quantum dot core reactants may remain at the heated temperature for greater than or about 30 minutes, greater than or about 45 minutes, greater than or about 60 minutes, greater than or about 75 minutes, greater than or about 90 minutes, greater than or about 100 minutes, greater than or about 120 minutes, or more, while the quantum dot core 202 is being formed.

Method 100 may include cooling the heated mixture of the quantum dot core 202 particles at optional operation 120. The cooling operation may lower the temperature of the heated mixture to less than or about 290° C., less than or about 280° C., less than or about 270° C., less than or about 260° C., less than or about 250° C., or less. The decrease in temperature may be characterized by a temperature ramp-down rate of less than or about 10° C./minute, less than or about 7.5° C./minute, less than or about 5° C./minute, less than or about 2.5° C./minute, less than or about 1° C./minute, or less. The cooling operation may reduce the temperature of the heated mixture of the quantum dot core 202 particles in preparation for the addition of the inner shell reactants to the quantum dot core particles. The reduced temperature may permit the inner shell reactants to distribute more evenly through the quantum dot core 202 particles before they react and form the inner shell 204 around the quantum dot core 202.

Method 100 may also include adding the inner shell layer reactants to the reduced-temperature mixture of quantum dot core particles at operation 125. The inner shell reactants may be rapidly added to the mixture of quantum dot core particles in a short period of time. The addition time may be less than or about 10 seconds, less than or about 7.5 seconds, less than or about 5 seconds, less than or about 2.5 seconds, less than or about 1 second, or less. The rapid addition of the inner shell reactants may reduce concentration centers of the reactants that can lead to wider variations in the characteristics of the inner shells, such as inner shell 204 surrounding quantum dot core 202 in the multilayered semiconductor particle 200. These inner shell characteristics may include the composition and thickness of the inner shell 204, among other characteristics. The inner shell 204 may have a thickness of greater than or about 0.5 nm, greater than or about 1 nm, greater than or about 1.5 nm, greater than or about 2 nm, greater than or about 2.5 nm, greater than or about 3 nm, greater than or about 3.5 nm, greater than or about 4 nm, greater than or about 4.5 nm, greater than or about 5 nm, greater than or about 5.5 nm, greater than or about 6 nm, or more.

The inner shell reactants may include a zinc-containing reactant and a selenium-containing reactant, among other reactants. The zinc-containing reactant may include anhydrous zinc acetate, and the selenium-containing reactant may include selenium combined with a complexing agent such as trioctylphosphine. The inner shell reactants may include additional compounds such as unsaturated or saturated alkyl hydrocarbons and organic acids. The unsaturated or saturated alkyl hydrocarbons may include 1-octadecene, and the organic acids may include oleic acid. The inner shell 204 formed from the inner shell reactants may include a zinc-selenium (ZnSe) material. The combined mixture of the inner shell reactants and the quantum dot core particles may be heated to facilitate the formation of the inner shell 204 on the quantum dot core 202. The combined mixture may be heated to a temperature of greater than or about 250° C., greater than or about 260° C., greater than or about 270° C., greater than or about 280° C., greater than or about 290° C., greater than or about 300° C., or more. The combined mixture may be heated to the heated temperature for greater than or about 1 minute, greater than or about 2.5 minutes, greater than or about 5 minutes, greater than or about 7.5 minutes, greater than or about 10 minutes, or more.

Method 100 may include adding outer shell layer reactants to the particle mixture at operation 130. The outer shell mixture may be rapidly added to the mixture of particles in a short period of time. The addition time may be less than or about 10 seconds, less than or about 7.5 seconds, less than or about 5 seconds, less than or about 2.5 seconds, less than or about 1 second, or less. The rapid addition of the outer shell reactants may reduce concentration centers of the reactants that can lead to wider variations in the characteristics of the outer shells, such as outer shell 206 surrounding inner shell 204 in the multilayered semiconductor particle 200. These outer shell characteristics may include the composition and thickness of the outer shell 206, among other characteristics. The outer shell 206 may have a thickness of greater than or about 1 nm, greater than or about 2 nm, greater than or about 3 nm, greater than or about 4 nm, greater than or about 5 nm, or more.

The combined mixture of the outer shell reactants and the particles may be maintained at the same heated temperature of the combined mixture of the inner shell reactants and the quantum dot cores 202. The temperature of the combined mixture of the outer shell reactants and the particles may be greater than or about 250° C., greater than or about 260° C., greater than or about 270° C., greater than or about 280° C., greater than or about 290° C., greater than or about 300° C., or more. The combined mixture may be held at the heated temperature for greater than or about 1 minute, greater than or about 2.5 minutes, greater than or about 5 minutes, greater than or about 7.5 minutes, greater than or about 10 minutes, or more, to facilitate the formation of the outer shell 206 on inner shell 204 of the multilayered semiconductor particle 200.

The outer shell reactants may include a zinc-containing reactant and a sulfur-containing reactant, among other reactants. The zinc-containing reactant may include anhydrous zinc acetate, and the sulfur-containing reactant may include sulfur combined with a complexing agent such as trioctylphosphine. The sulfur-containing reactant may be or include one or more of 1-octanethiol, 1-dodecanethiol, 1-octadecanethiol, tributylphosphine sulphide, cyclohexyl isothiocyanate, α-toluenethiol, ethylene trithiocarbonate, allyl mercaptan, bis(trimethylsilyl) sulphide, trioctylphosphine sulphide, 1-undecanethiol, 1-hexadecanethiol, 1-tetradecanethiol, 1-decanethiol, 2-phenylethanethiol, 4-methylbenzenethiol, 4-methoxybenzyl mercaptan, tert-dodecylmercaptan, 2-,3-,10-mercaptopinane, cyclohexanethiol, and di-tert-butyl disulfide, among other sulfur-containing reactants. The sulfur-containing reactant may be or include one or more of a poly(ethylene glycol) methyl ether thiol of molecular weight 600 to 3000, a poly(ethylene glycol) dithiol of molecular weight 600 to 3000, a alkanedithiol of formula HSCH₂(CH₂)ₙCH₂SH (n=2-30), trimethylolpropane, tris(3-mercaptopropionate), 2,2′-(ethylenedioxy)diethanethiol, among other sulfur-containing reactants.

The outer shell reactants may include additional compounds such as unsaturated or saturated alkyl hydrocarbons and organic acids. The unsaturated or saturated alkyl hydrocarbons may be or include 1-octadecene, and the organic acids may be or include oleic acid. The outer shell 206 formed from the outer shell reactants may include a zinc sulfide (ZnS) material. The outer shell 206 provides improved binding and dispersion properties to the multilayered semiconductor particle 200 when it is added to a polymer binder. In embodiments of the multilayered semiconductor particle 200 that include an outer shell 206 which contains ZnS material, the disulfide bonds of the sulfur component may provide crosslinking between the particle and the surrounding polymer binder. The crosslinking may facilitate a more even dispersion of the particles in the polymer binder and reduce the number of emission hot spots and dark spots in a layer of the quantum dot material.

Method 100 may include cooling the mixture of the fully-formed multilayered semiconductor particles 200 at optional operation 135. In embodiments, operation 135 may include more than one cooling stage characterized by different cooling ramp-down rates. The different cooling stages may include a more rapid initial cooling of the particles to more precisely define the growth endpoint of the outer shell 206 and the size of the multilayered semiconductor particle 200. The heated mixture of fully-formed particles may be cooled in a first cooling stage characterized by a first temperature ramp-down rate, followed by a second cooling stage characterized by a second cooling ramp-down rate. The first temperature ramp-down rate may be greater than or about 5° C./minute, greater than or about 6° C./minute, greater than or about 7° C./minute, greater than or about 8° C./minute, greater than or about 9° C./minute, greater than or about 10° C./minute, or more. The second temperature ramp-down rate may be less than or about 4° C./minute, less than or about 3° C./minute, less than or about 2° C./minute, less than or about 1° C./minute, or less. A transition temperature from the first cooling stage to the second cooling stage may occur when the mixture of the fully-formed multilayered semiconductor particles 200 is characterized by a temperature of about 120° C., about 110° C., about 100° C., about 90° C., or about 80° C., among other transition temperatures. Operation 135 may reach completion when the mixture of the fully-formed multilayered semiconductor particles 200 is characterized by a temperature of less than or about 30° C.

Method 100 may include separating the multilayered semiconductor particles 200 from the residual components of the mixture in which they were formed at optional operation 140. In embodiments, the mixture of the fully-formed multilayered semiconductor particles 200 may include liquid organic compounds, including hydrocarbons, organic acids, organo-phosphine compounds, and organo-sulfur compounds, as well as residual reactants of the core, inner shell, and outer shell of the particles. These liquid organic compounds may be separated from the multilayered semiconductor particles 200 by decanting the supernatant liquid from the concentrated mixture of the particles. The concentrated mixture of the particles may be mixed with one or more volatile organic solvents such as hexane and acetone, among other organic solvents. The solvent mixture may be centrifuged to separate the mixture into sediment containing the multilayered semiconductor particles 200 and another supernatant containing the added organic solvents and an additional portion of the residual liquid organic compounds from the particle formation mixture. The supernatant may be separated from the sediment containing the multilayered semiconductor particles 200. The separated sediment may be contacted with more volatile organic solvents and centrifuged and separated for one or more additional washing cycles to produce an isolated batch of the multilayered semiconductor particles 200. The isolated batch of the multilayered semiconductor particles 200 may be contacted with a binder polymer composition and stored until use. The binder polymer composition may include an acrylate compound. The acrylate compound may be or include 1,6-hexanediol diacrylate.

In method 100, the various reactant and particle mixtures may be characterized by low moisture. The mixtures may be characterized by moisture levels of less than or about 1 wt. %, less than or about 0.75 wt. %, less than or about 0.5 wt. %, less than or about 0.25 wt. %, less than or about 0.1 wt. %, less than or about 0.05 wt. %, or less. The mixtures may be characterized as free of hydrated compounds that have one or more water molecules incorporated into the compound. The low moisture levels in the reactants and mixtures may reduce the number of side products produced instead of the multilayered semiconductor particles 200. The low moisture levels may provide mixtures with lower amounts of semiconductor hydroxide compounds such as zinc hydroxide, selenium hydroxide, and tellurium hydroxide, among other semiconductor hydroxides, that can precipitate out of the mixture to prevent the semiconductor material from being incorporated into the multilayered semiconductor particles 200.

Furthermore, in method 100, the various reactant and particle mixtures in heated states (e.g., greater than or about 80° C.) may be held in anoxic atmospheres to reduce or prevent the oxidation of compounds in the mixtures. The reactant and particle mixtures may be heated in an anoxic atmosphere to reduce or prevent the oxidation of zinc-containing compounds, selenium-containing compounds, tellurium-containing compounds, and trialkyl-phosphine compounds, among other compounds in the mixtures. The anoxic atmospheres may also reduce the fire hazard risk during the formation of the quantum dot particles. The reactants and mixtures include many pyrophoric compounds that may be heated to temperatures of 300° C. or more. In an oxygen-containing environment such as ambient air, there is a possibility that these reactants and mixtures may catch fire at such temperatures. The reactant and particle mixtures in heated states may be held in anoxic atmospheres that include dry nitrogen (N₂) and/or argon (Ar), among other inert gases. These anoxic atmospheres may be characterized by levels of molecular oxygen (O₂) of less than or about 1 wt. %, less than or about 0.75 wt. %, less than or about 0.5 wt. %, less than or about 0.25 wt. %, less than or about 0.1 wt. %, less than or about 0.05 wt. %, or less.

Method 100 may include adding antioxidant reactants to the particle mixture at operation 145. However, it is contemplated that the antioxidant reactants may be added to the particle mixture at any stage during particle formation. The antioxidant may be characterized by a boiling point of greater than or about 100° C. At boiling points less than 100° C., the antioxidant may be prone to diffusion and/or evaporation. Accordingly, higher molecular weight antioxidants may perform better than lower molecular weight antioxidants. The antioxidant reactants may include a phosphorous-containing material, among other materials. In embodiments, the phosphorous-containing material may be an organic ligand including phosphite or phosphine groups able to bind with the particle mixture, such as the zinc-containing outer shell.

In embodiments, the phosphorous-containing material may include any material including phosphorous, such as, but not limited to, triisopropyl phosphite (TIPP), bis(2,4-di-tert-butylphenyl) pentaerythritol diphosphate (B PEDP), tris(2, 4-di-tert-butylphenyl)phosphite (TDTBPP), triethylphosphite, tris(2-ethylhexylphosphite), tris(trimethylsilyl)phosphite, triphenylphosphite, triphenyl phosphine, tris(4-methoxyphenyl)phosphine, tris(1-pyrrolidinyl)phosphine, tri(2-furyl)phosphine, or tris(dimethylamino)phosphine. It is also contemplated that the antioxidant, such as the phosphorous-containing material, may include reactive functional groups. The reactive functional groups may be polymerized, cured, or crosslinked with other components in the quantum dot material, such as the ink used to form quantum dot particles. For example, the phosphorous-containing material may include triallyl phosphite, triallyl phosphine, divinylphenyl phosphine, diallyl-N,N-diisopropylphospharmidite, or tris-(4-vinylbenzyl)phosphine. However, other phosphorous-containing materials are contemplated and, in embodiments, the antioxidant may not be limited to phosphorous-containing materials.

In embodiments, the antioxidant, such as the phosphorous-containing material, may be bonded to the zinc-containing outer shell. For example, the antioxidant, such as the phosphorous-containing material, may be covalently bonded to the zinc-containing outer shell.

The antioxidant may improve the stability of quantum dot materials by consuming oxygen that would otherwise react with the quantum dot materials. If the antioxidant were not present, the quantum dot materials may undergo oxidation and the quantum dot materials may undergo photodegradation. Phosphites in the phosphorous-containing material may undergo oxidation and form phosphates. By undergoing oxidation, the phosphites in the antioxidant may prevent oxygen from reacting with the quantum dot materials, thereby improving the stability and shelf life of the quantum dot materials. Accordingly, when an antioxidant is present in the quantum dot materials, the various reactant and particle mixtures in heated states (e.g., greater than or about 80° C.) may need not be held in anoxic atmospheres. The presence of oxygen may not affect the quantum dot materials, but may instead react with the antioxidant. Furthermore, the various reactant and particle mixtures of the quantum dot materials may also be exposed to white light during fabrication, which may oxidize conventional quantum dot materials.

Each of the multilayered semiconductor particles 200 may be characterized by a longest dimension (e.g., a diagonal length) that is less than or about 4 nm, less than or about 3.5 nm, less than or about 3 nm, less than or about 2.5 nm, less than or about 2 nm, or less. Method 100 may form multilayered semiconductor particles 200 that may be characterized by an increased sharpness and fewer secondary emission peaks than quantum dot particles made by conventional methods. In embodiments, the light emitted by the multilayer semiconductor particles 200 may be characterized by a peak wavelength emission of less than or about 500 nm, less than or about 490 nm, less than or about 480 nm, less than or about 470 nm, less than or about 460 nm, less than or about 450 nm, less than or about 440 nm, less than or about 430 nm, less than or about 420 nm, less than or about 410 nm, less than or about 400 nm, less than or about 390 nm, less than or about 380 nm, or less. The light emitted by the multilayer semiconductor particles 200 may be characterized by a peak wavelength emission of less than or about 455 nm. The light emitted by the multilayer semiconductor particles 200 may have a narrowband (i.e., sharp) color profile that is characterized by a full-width-half-maximum (FWHM) primary wavelength emission peak that is less than or about 40 nm, less than or about 35 nm, less than or about 30 nm, less than or about 25 nm, less than or about 20 nm, less than or about 15 nm, less than or about 10 nm, less than or about 5 nm, less than or about 2.5 nm, less than or about 1 nm, or less.

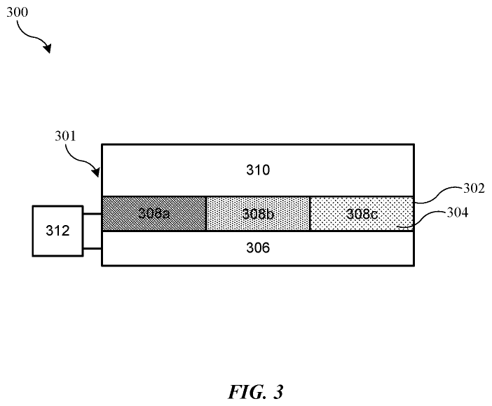

Referring now to FIG. 3, a simplified cross-section of a display device 300 is shown that includes a pixel structure 301. The pixel structure 301 may include a photoluminescent region 302, which may contain photoluminescent material 304. The photoluminescent material 304 may include one or more multilayered semiconductor particles (i.e., quantum dot particles) having an antioxidant, such as a phosphorous-containing material, according to embodiments of the present technology. In embodiments, the quantum dot particles (i.e., quantum dot material) of the photoluminescent material 304 may be blue quantum dot particles (i.e., blue quantum dot material). Pixel structure 301 of display device 300 may include a light source 306. The photoluminescent region and/or photoluminescent material may be positioned on the light source 306. The light source 306 may excite three areas of quantum dot particles 308a-c that are operable to emit light of different colors upon being excited with the light source 306. The first quantum dot area 308a may be operable to emit blue light, the second quantum dot area 308b may be operable to emit green light, and the third quantum dot area 308c may be operable to emit red light. The multilayered semiconductor particles according to embodiments of the present technology may be incorporated into the first quantum dot area 308a and may be operable to emit a sharp blue with a peak narrowband emission wavelength of less than or about 455 nm.

The display device 300 may be operable to excite the areas of quantum dot particles 308a-c at varying intensities with the light source 306. The light source 306 may include one or more light-emitting-diode structures operable to emit light at shorter, more energetic wavelengths than the light emitted by the areas of quantum dot particles 308a-c. The light source 306 may be operable to emit an ultraviolet excitation light characterized by a peak emission wavelength of less than or about 350 nm. In embodiments, the light source 306 may be operable to emit white light characterized by a broad emission of light across the visible spectrum (e.g., 380 nm to 750 nm).

The display device 300 may be operable to display an image by activating the light source 306 to excite the areas of quantum dot particles 308a-c, which emit colored light through a translucent front panel 310 that projects the image. A controller 312 may be coupled through electronic circuitry (not shown) to the light source 306 and the areas of quantum dot particles 308a-c. The controller 312 may be operable to receive input signals for the display of an image and transmit output signals that activate and deactivate portions of the light source 306 and the areas of quantum dot particles 308a-c.

Forming the display device 300 may include forming a light source 306, such as a light emitting diode structure on a substrate (not shown), forming a photoluminescent region 302 on the light emitting diode structure, and forming a photoluminescent material 304 in the photoluminescent region 302. As previously discussed, the photoluminescent material 304 may include a plurality of multilayered semiconductor particles including an antioxidant, such as the multilayered semiconductor particles according to the present disclosure. In embodiments, the photoluminescent material may include a blue quantum dot material. While forming the display device 300, the photoluminescent material may be handled in a presence of oxygen or ambient white light.

Embodiments of the present technology permit the making of multilayered semiconductor particles (i.e., quantum dot particles) that are characterized by improved PLQY. The embodiments include the addition of an antioxidant, such as a phosphorous-containing material, that may serve as a sacrificial compound to undergo oxidation. By including the oxidant, materials in the multilayered semiconductor particles crucial to performance of photoluminescent materials may be less prone to photodegradation due to oxidation. The incorporation of the antioxidant may allow the quantum dot particles to be fabricated in oxygen-containing environments, such as atmosphere. This may reduce the complexity of fabrication compared to conventional technologies and improve the lifespan of the quantum dot particles.

In the preceding description, for the purposes of explanation, numerous details have been set forth in order to provide an understanding of various embodiments of the present technology. It will be apparent to one skilled in the art, however, that certain embodiments may be practiced without some of these details, or with additional details. For example, other substrates that may benefit from the wetting techniques described may also be used with the present technology.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included. Where multiple values are provided in a list, any range encompassing or based on any of those values is similarly specifically disclosed.

As used herein and in the appended claims, the singular forms “a”, “an”, and “the” include plural references unless the context clearly dictates otherwise. Thus, for example, reference to “a light emitting diode structure” includes a plurality of such structures, and reference to “the photoluminescent region” includes reference to one or more photoluminescent regions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A multilayered semiconductor particle comprising:
a zinc-containing core;
a zinc-and-selenium-containing inner shell on the zinc-containing core;
a zinc-containing outer shell on the zinc-and-selenium-containing inner shell; and
a phosphorous-containing material in contact with the zinc-containing outer shell, wherein the phosphorous-containing material comprises triisopropyl phosphite (TIPP), bis(2,4-di-tert-butylphenyl) pentaerythritol diphosphate (B PEDP), tris(2, 4-di-tert-butylphenyl)phosphite (TDTBPP), triethylphosphite, tris(2-ethylhexylphosphite), tris(trimethylsilyl)phosphite, triphenylphosphite, triphenyl phosphine, tris(4-methoxyphenyl)phosphine, tris(1-pyrrolidinyl)phosphine, tri(2-furyl)phosphine, tris(dimethylamino)phosphine, triallyl phosphite, triallyl phosphine, divinylphenyl phosphine, diallyl-N,N-diisopropylphospharmidite, or tris-(4-vinylbenzyl)phosphine.

2. The multilayered semiconductor particle of claim 1, wherein the zinc-containing core further comprises sulfur, selenium, or tellurium.

3. The multilayered semiconductor particle of claim 1, wherein the zinc-and-selenium-containing inner shell further comprises tellurium or sulfur.

4. The multilayered semiconductor particle of claim 1, wherein the zinc-containing outer shell further comprises sulfur.

5. The multilayered semiconductor particle of claim 1, wherein each of the multilayered semiconductor particle is characterized by a longest dimension of less than or about 4 nm.

6. The multilayered semiconductor particle of claim 1, wherein the phosphorous-containing material is characterized by a boiling point of greater than or about 100° C.

7. The multilayered semiconductor particle of claim 1, wherein the phosphorous-containing material comprises bis(2,4-di-tert-butylphenyl) pentaerythritol diphosphate (B PEDP), or tris(2, 4-di-tert-butylphenyl)phosphite (TDTBPP).

8. A pixel structure comprising:
a light emitting diode structure operable to generate light characterized by a peak emission wavelength of greater than or about 350 nm; and
a photoluminescent region containing a photoluminescent material positioned on the light emitting diode structure, wherein the photoluminescent region comprises a plurality of multilayered semiconductor particles comprising an antioxidant.

9. The pixel structure of claim 8, wherein the antioxidant comprises phosphorous and is characterized by a boiling point of greater than or about 100° C.

10. The pixel structure of claim 8, wherein:
the antioxidant comprises a phosphorous-containing material; and
the phosphorous-containing material comprises triisopropyl phosphite (TIPP), bis(2,4-di-tert-butylphenyl) pentaerythritol diphosphate (B PEDP), tris(2, 4-di-tert-butylphenyl)phosphite (TDTBPP), triethylphosphite, tris(2-ethylhexylphosphite), tris(trimethylsilyl)phosphite, triphenylphosphite, triphenyl phosphine, tris(4-methoxyphenyl)phosphine, tris(1-pyrrolidinyl)phosphine, tri(2-furyl)phosphine, tris(dimethylamino)phosphine, triallyl phosphite, triallyl phosphine, divinylphenyl phosphine, diallyl-N,N-diisopropylphospharmidite, or tris-(4-vinylbenzyl)phosphine.

11. The pixel structure of claim 8, wherein the plurality of multilayered semiconductor particles comprise:
a zinc-containing core;
a zinc-and-selenium-containing inner shell on the zinc-containing core; and
a zinc-containing outer shell on the zinc-and-selenium-containing inner shell.

12. The pixel structure of claim 8, wherein the photoluminescent material comprises a quantum dot material.

13. The pixel structure of claim 12, wherein the quantum dot material comprises a blue quantum dot material.

14. The pixel structure of claim 8, wherein each of the multilayered semiconductor particles is characterized by a longest dimension of less than or about 4 nm.

15. A method of fabricating a display comprising:
forming a light emitting diode structure on a substrate;
forming a photoluminescent region on the light emitting diode structure; and
forming a photoluminescent material in the photoluminescent region, wherein the photoluminescent material comprises a plurality of multilayered semiconductor particles comprising an antioxidant.

16. The method of fabricating a display of claim 15, wherein the photoluminescent material comprises a blue quantum dot material.

17. The method of fabricating a display of claim 15, wherein
the antioxidant comprises a phosphorous-containing material; and
the phosphorous-containing material comprises triisopropyl phosphite (TIPP), bis(2,4-di-tert-butylphenyl) pentaerythritol diphosphate (B PEDP), tris(2, 4-di-tert-butylphenyl)phosphite (TDTBPP), triethylphosphite, tris(2-ethylhexylphosphite), tris(trimethylsilyl)phosphite, triphenylphosphite, triphenyl phosphine, tris(4-methoxyphenyl)phosphine, tris(1-pyrrolidinyl)phosphine, tri(2-furyl)phosphine, tris(dimethylamino)phosphine, triallyl phosphite, triallyl phosphine, divinylphenyl phosphine, diallyl-N,N-diisopropylphospharmidite, or tris-(4-vinylbenzyl)phosphine.

18. The method of fabricating a display of claim 15, wherein the photoluminescent material is characterized by a longest dimension of less than or about 4 nm.

19. The method of fabricating a display of claim 15, further comprising:
handling the photoluminescent material in a presence of oxygen or ambient white light during subsequent fabrication operations.

20. The method of fabricating a display of claim 15, wherein the plurality of multilayered semiconductor particles comprise:
a zinc-containing core;
a zinc-and-selenium-containing inner shell on the zinc-containing core; and
a zinc-containing outer shell on the zinc-and-selenium-containing inner shell.
